(19) United States
(12) Patent Application Publication
(10) Pub. No.: US 2025/0296046 A1
(43) Pub. Date: Sep. 25, 2025

(54) WASTE GAS SCRUBBER

(71) Applicant: Samsung Electronics Co., Ltd., Suwon-si (KR)

(72) Inventors: Hyunsik KIM, Suwon-si (KR); Hyunwoo PARK, Suwon-si (KR); Inchan BAEK, Suwon-si (KR); Jaehyun KIM, Suwon-si (KR); Taijong SUNG, Suwon-si (KR); Hyunsoo JO, Suwon-si (KR)

(73) Assignee: Samsung Electronics Co., Ltd., Suwon-si (KR)

(21) Appl. No.: 18/947,120

(22) Filed: Nov. 14, 2024

(30) Foreign Application Priority Data
Mar. 22, 2024 (KR) 10-2024-0039978

(51) Int. Cl. B01D 53/88; B01D 47/06; B01D 53/00; B01D 53/75; B01D 53/86; B01J 38/04

(52) U.S. Cl. CPC B01D 53/885; B01D 47/06; B01D 53/005; B01D 53/75; B01D 53/8668; B01D 53/8671; B01J 38/04; B01D 2257/2025; B01D 2257/2045; B01D 2257/402; B01D 2257/406; B01D 2257/553; B01D 2257/556; B01D 2258/0216

(57) ABSTRACT

A waste gas scrubber includes a reaction chamber configured to decompose waste gas, at least one heater configured to heat the waste gas flowing into the reaction chamber, a fine powder separation device configured to emit compressed air, and a monolith catalyst including a catalyst support, a plurality of catalyst inner cells, and at least one catalyst material, the catalyst support in the reaction chamber and configured to support the plurality of catalyst inner cells, and the at least one catalyst material configured to cause a chemical reaction with the heated waste gas, the catalyst support including a first surface at which a first end of each of the plurality of catalyst inner cells is exposed, and a second surface at which a second end of each of the plurality of catalyst inner cells is exposed.

### CROSS-REFERENCE TO RELATED APPLICATION

This U.S. non-provisional application claims the benefit of priority under 35 U.S.C. § 119 to Korean Patent Application No. 10-2024-0039978, filed on Mar. 22, 2024, in the Korean Intellectual Property Office, the disclosure of which is incorporated by reference herein in its entirety.

### BACKGROUND

Various example embodiments of the inventive concepts relate to a waste gas scrubber, a system including the waste gas scrubber, and/or a method of operating a waste gas scrubber, etc., and more particularly, to technology which performs oxidation processing on an organic compound included in waste gas by using a catalyst.

Various example embodiments of the inventive concepts relate to a waste gas scrubber, a system including the waste gas scrubber, and/or a method of operating a waste gas scrubber, etc., and more particularly, to a waste gas scrubber for semiconductor manufacturing equipment, which burns and discharges a process gas after a manufacturing process is performed by the semiconductor manufacturing equipment. Generally, a waste gas processing apparatus is installed and operated at a rear end of semiconductor manufacturing equipment to process a process gas.

Semiconductor devices are manufactured through various manufacturing processes such as oxidation, etching, deposition, and/or photo processes, etc., and toxic chemicals and/or chemical gas are used in the manufacturing processes. For example, toxic gases such as SiH₄, SiH₂, NO, AsH₃, PH₃, NH₃, N₂O, and/or SiH₂Cl₂, etc., are used in a chemical vapor deposition (CVD) process, an ion implantation process, an etching process, and/or a diffusion process, etc.

Based on various manufacturing processes performed when manufacturing a semiconductor device, various kinds of waste gases are emitted from toxic chemicals and/or chemical gases used in each manufacturing process, and such waste gases are harmful to the human body, are flammable, and/or are corrosive, etc., and may cause accidents such as such as fire, etc. Also, when the waste gas is discharged into the atmosphere, serious environmental pollution occurs, and thus, a purification process has to be performed before a gas is discharged into the atmosphere.

Some scrubbers of the related art are based on direct combustion of directly discharge carbon by using liquefied natural gas (LNG) and have safety problems caused by the use of LNG. Other scrubbers of the related art are based on plasma processing which may process a decomposition-difficult greenhouse gas with high efficiency, but have problems related to energy efficiency being reduced because the amount of power used is high. Scrubbers of the related art using an electric heater use an electric heater, and due to this, have a limitation in removing greenhouse gases which are decomposed at high temperatures.

Therefore, a waste gas scrubber has been proposed which performs an oxidation processing on an organic compound included in a waste gas at a relatively low temperature by using a catalyst to decrease and/or minimize the occurrence of hydrocarbon and enhance energy efficiency.

There are many cases where waste gas generated during a semiconductor manufacturing process mainly includes silicone, and the waste gas scrubber has a characteristic where a large amount of fine powders are produced when decomposing the waste gas including silicone. An example of a chemical formula for generating fine powders is as follows.

SiH₄(gas)+2O₂-->SiO₂(fine powder)+2H₂O

A waste gas scrubber of the related art using a catalyst has problems such as fine powders accumulating on a catalyst surface, thereby reducing the reactivity of the catalyst, and thus, a method for removing fine powders piled up on a catalyst surface is desired and/or needed.

### SUMMARY

Various example embodiments of the inventive concepts provide a waste gas scrubber which may remove fine powders piled up on a catalyst surface to decrease and/or prevent the plugging of a scrubber (particularly, the plugging of a catalyst, etc.) and/or improve and/or enhance the decomposition efficiency of a waste gas.

However, the example embodiments of the inventive concepts are not limited thereto, and other advantages and/or benefits of one or more of the example embodiments may be clearly understood by those of ordinary skill in the art from the descriptions below.

A waste gas scrubber according to at least one example embodiment includes a waste gas inlet, a reaction chamber configured to decompose waste gas flowing in through the waste gas inlet, at least one heater configured to heat the waste gas flowing into the reaction chamber, a fine powder separation device configured to emit compressed air, a monolith catalyst including a catalyst support, a plurality of catalyst inner cells, and at least one catalyst material, the catalyst support in the reaction chamber and configured to support the plurality of catalyst inner cells, and the at least one catalyst material configured to cause a chemical reaction with the heated waste gas, the catalyst support including, a first surface at which a first end of each of the plurality of catalyst inner cells is exposed, and a second surface at which a second end of each of the plurality of catalyst inner cells is exposed, and the waste gas inlet and the fine powder separation device face the first surface of the catalyst support.

In at least one example embodiment, a waste gas scrubber is provided where the fine powder separation device is configured to emit the compressed air toward the first surface of the catalyst support.

In at least one example embodiment, a waste gas scrubber is provided where the waste gas inlet and the fine powder separation device are disposed on the first surface of the catalyst support.

In at least one example embodiment, a waste gas scrubber is provided where the fine powder separation device includes at least one air pulse control valve and at least one air pulse nozzle connected to the air pulse control valve, the at least one air pulse nozzle configured to emit the compressed air based on whether the air pulse control valve is open or closed.

In at least one example embodiment, a waste gas scrubber is provided where the air pulse nozzle includes a diffuser nozzle, an air-knife nozzle, or a circular nozzle.

In at least one example embodiment, the waste gas scrubber may further include a wet tank and a wet tower each including at least one liquid injection nozzle, the wet tank connected to the reaction chamber and the wet tower, and the wet tank and the wet tower are configured to wet-process waste gas flowing into the wet tank and the wet tower from the reaction chamber.

In at least one example embodiment, the waste gas scrubber may further include an air pulse controller configured to control the fine powder separation device by, controlling an opening or closing of the air pulse control valve based on a desired time period for emitting the compressed air, a desired time schedule for emitting the compressed air, a desired number of times to emit the compressed air, a sensed pressure of the reaction chamber, or any combinations thereof.

In at least one example embodiment, a waste gas scrubber is provided where the plurality of catalyst inner cells extend in a vertical direction.

In at least one example embodiment, a waste gas scrubber is provided where an internal space of the reaction chamber is divided into a first portion and a second portion spaced apart from the first portion, the monolith catalyst between the first portion and the second portion, the waste gas moves from the first portion to the second portion via the monolith catalyst, and the fine powder separation device is further configured to emit the compressed air in response to an internal pressure of the first portion being greater than an internal pressure of the second portion.

In at least one example embodiment, a waste gas scrubber is provided where the fine powder separation device is configured to emit the compressed air in response to a difference between the internal pressure of the first portion and the internal pressure of the second portion being within a desired pressure range.

A waste gas scrubber according to at least one example embodiment includes a waste gas inlet, a reaction chamber connected to the waste gas inlet, the reaction chamber including an internal space, the internal space divided into a first portion and a second portion, at least one heater configured to heat the reaction chamber, a catalyst support arranged in the reaction chamber, the catalyst support configured to support a plurality of catalyst inner cells, each of the plurality of catalyst inner cells having at least one catalyst bonded to an exposed portion of each of the plurality of catalyst inner cells, the first portion above the catalyst support in a vertical direction and the second portion below the catalyst support in the vertical direction, an air pulse control valve disposed outside the reaction chamber, and an air pulse nozzle connected to the air pulse control valve, the air pulse nozzle configured to emit compressed air into the reaction chamber, and the waste gas inlet and the air pulse nozzle are connected to the first portion of the reaction chamber.

In at least one example embodiment, a waste gas scrubber is provided where the air pulse nozzle is configured to intermittently emit the compressed air into the reaction chamber for a desired amount of time.

In at least one example embodiment, a waste gas scrubber is provided where the air pulse nozzle is configured to emit the compressed air into the reaction chamber based on a desired time schedule.

In at least one example embodiment, a waste gas scrubber is provided where the air pulse nozzle is configured to emit the compressed air into the reaction chamber at a desired frequency.

In at least one example embodiment, a waste gas scrubber is provided where the air pulse nozzle is configured to emit the compressed air into the reaction chamber in response to a pressure difference between the first portion and the second portion of the reaction chamber being between 5 mmH₂O to 140 mmH₂O.

In at least one example embodiment, the waste gas scrubber may further include a wet tank and a wet tower each including at least one liquid injection nozzle, each of the at least one liquid injection nozzles configured to emit liquid, the wet tank being connected to the reaction chamber, the wet tower being connected to the reaction chamber through the wet tank, the air pulse control valve and the air pulse nozzle are configured to separate fine powder accumulated on at least one surface of the catalyst support from the at least one surface of the catalyst support, and the wet tank and the wet tower are configured to, collect the fine powder separated from the at least one surface of the catalyst support in liquid emitted from the at least one liquid injection nozzle, and discharge the collected fine powder from the waste gas scrubber.

A waste gas scrubber according to at least one example embodiment includes a waste gas inlet, a reaction chamber configured to receive a waste gas from the waste gas inlet, at least one heater configured to heat the waste gas in the reaction chamber, a monolith catalyst including a catalyst support arranged in the reaction chamber, a plurality of catalyst inner cells supported by the catalyst support, and at least one catalyst material configured to cause a chemical reaction with the waste gas heated by the heater, a fine powder separation device configured to separate fine powder from at least one surface of the catalyst support, the fine powder generated by the chemical reaction between the at least one catalyst material and the waste gas, a wet tank connected to the reaction chamber, the wet tank configured to perform a primary wet-process on the waste gas, a wet tower connected to the wet tank, the wet tower configured to perform a secondary wet-process on the waste gas, a drain port on a bottom surface of the wet tank, and a waste gas discharge port on an upper portion of the wet tower.

In at least one example embodiment, a waste gas scrubber is provided where the fine powder separation device includes an air pulse control valve provided outside the reaction chamber, and an air pulse nozzle provided in the reaction chamber, the air pulse nozzle configured to emit compressed air based on the air pulse control valve.

In at least one example embodiment, a waste gas scrubber is provided where the wet tank is installed at a lower portion or a side portion of the reaction chamber, the at least one heater is configured to heat the waste gas, the at least one catalyst material causes a chemical reaction with the waste gas, the wet tank and the wet tower are configured to wet-process the heated waste gas, and the waste gas discharge port is configured to discharge the wet-processed waste gas.

In at least one example embodiment, a waste gas scrubber is provided where the wet tank is installed at a lower portion or a side portion of the reaction chamber, the fine powder separation device is configured to separate the fine powder from at least one surface of the catalyst support, the wet tank and the wet tower are configured to wet-process the separated fine powder, and the waste gas discharge port is configured to discharge the wet-processed fine powder.

### BRIEF DESCRIPTION OF THE DRAWINGS

Various example embodiments will be more clearly understood from the following detailed description taken in conjunction with the accompanying drawings in which:

FIG. 1A is a schematic diagram for describing a waste gas scrubber according to some example embodiments;

FIG. 1B is a schematic diagram for describing a flow of a waste gas in a waste gas scrubber according to some example embodiments;

FIG. 2A is a schematic diagram for describing a fine powder removal principle of a waste gas scrubber according to some example embodiments;

FIG. 2B is an enlarged view of a region EX1 of FIG. 2A according to at least one example embodiment; and

FIG. 2C is an enlarged view of a region EX2 of FIG. 2A according to at least one example embodiment.

### DETAILED DESCRIPTION

Various advantages and/or features of one or more of the example embodiments of the inventive concepts and implementation methods thereof will be described through the following example embodiments discussed with reference to the accompanying drawings.

However, the example embodiments of the inventive concepts are not limited to the following illustrated example embodiments but may be embodied in different forms and may be used through mutual intersection, and the example embodiments may enable the completion of description of the inventive concepts. Also, example embodiments may be provided so that this disclosure will be thorough and complete, and will fully convey the scope of the inventive concepts to those of ordinary skill in the art.

In the drawings, the relative sizes of layers and regions may be exaggeratedly illustrated for clarity and convenience of description.

Also, “and/or” may include one or more combinations and each of described elements.

Furthermore, one element being referred to as being “connected to” or “coupled to” another element may include a case which is directly connected or coupled to another element or a case where another element is disposed therebetween. On the other hand, one element being referred to as being “directly connected to” or “directly coupled to” another element may represent that another element is not disposed therebetween.

The terms used herein may be for describing the example embodiments and may not limit the inventive concepts. Unless otherwise defined, all terms (including technical and scientific terms) used herein have the same meaning as commonly understood by one of ordinary skill in the art to which the inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, various example embodiments will be described in detail with reference to the accompanying drawings. Like reference numerals refer to like elements in the drawings, and their repeated descriptions are omitted.

Herein, a horizontal direction may include a first horizontal direction (e.g., an X direction) and a second horizontal direction (e.g., a Y direction), which intersect with each other. A direction intersecting with the first horizontal direction (e.g., the X direction) and the second horizontal direction (e.g., the Y direction) may be referred to as a vertical direction (e.g., a Z direction). Herein, a vertical level may be referred to as a height level with respect to a vertical direction (e.g., a Z direction) of an arbitrary element.

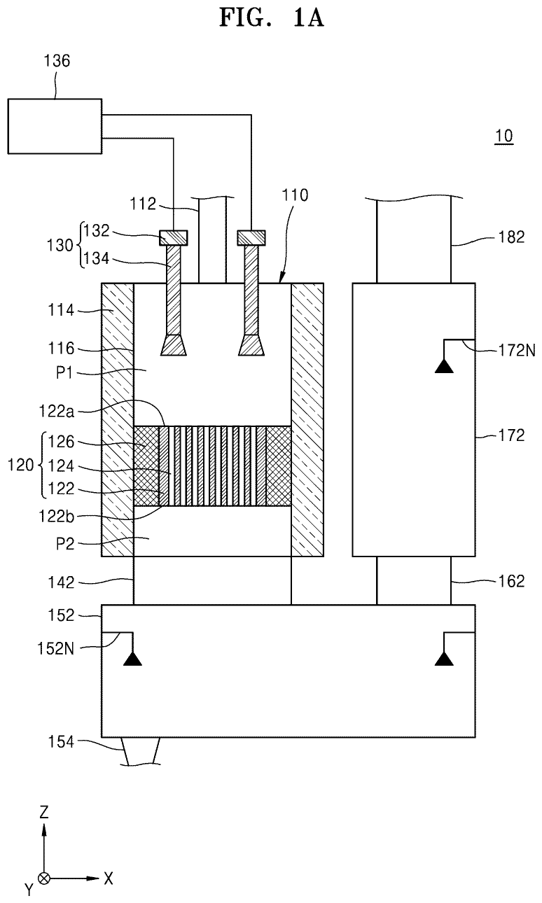

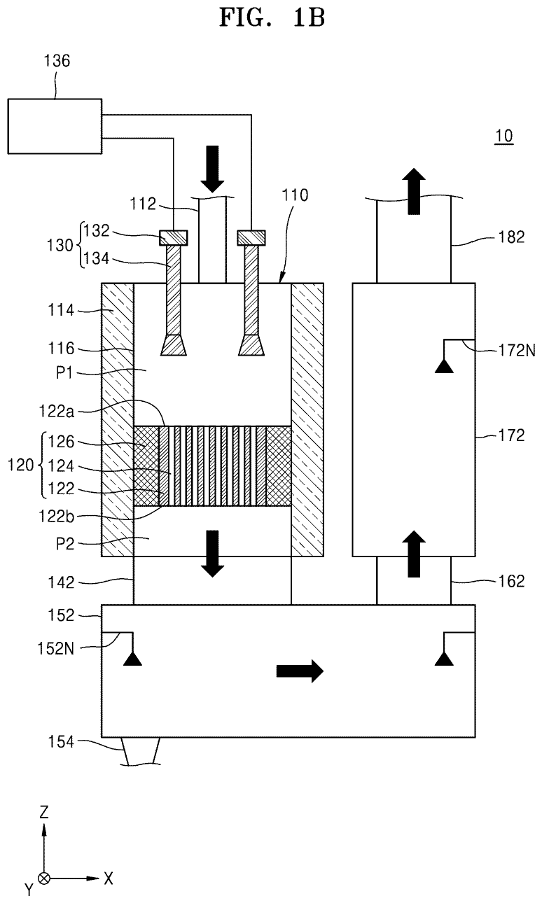

FIG. 1A is a schematic diagram for describing a waste gas scrubber 10 according to some example embodiments.

FIG. 1B is a schematic diagram for describing a flow of a waste gas in a waste gas scrubber according to some example embodiments.

Referring to FIGS. 1A and 1B, the waste gas scrubber 10 may include a waste gas reaction unit 110 (e.g., a waste gas reaction chamber, a waste gas reaction container, etc.), a catalyst processing unit 120 (e.g., a catalyst processing device, a catalyst processor, etc.), and/or a fine powder separation unit 130 (e.g., a fine powder separator, a fine powder separation device, etc.), etc., but the example embodiments are not limited thereto, and for example, the waste gas scrubber 10 may include a greater or lesser number of constituent elements.

For example, the waste gas scrubber 10 may be a point of unit (POU) scrubber which is installed at a rear end of semiconductor manufacturing equipment, but is not limited thereto. This may be merely at least one example embodiment for understanding the inventive concepts, and the waste gas scrubber 10 may be used for processing at least one waste gas generated through various processes, in addition to processing at least one waste gas generated from a semiconductor manufacturing process line, etc., but the example embodiments are not limited thereto. For example, the waste gas scrubber 10 may be applied to waste gas purification and/or processing facilities using at least one catalyst, such as a regenerative thermal oxidizer (RTO) and/or an outdoor scrubber, etc.

When the waste gas scrubber 10 is connected to a semiconductor process line, a waste gas penetrating into the waste gas scrubber 10 may include at least one of at least one basic gas, at least one acidic gas, and/or at least one volatile organic material, etc., but is not limited thereto. The basic gas may include, for example, ammonia (NH₃), etc., but is not limited thereto. The acidic gas may include, for example, hydrochloric acid (HCl), hydrogen fluoride (HF), diborane (B₂H₆), and/or boron trichloride (BCl₃), etc., but is not limited thereto.

The waste gas reaction unit 110 may include at least one waste gas inlet 112 where the penetration and/or insertion of a waste gas starts, at least one heater 114 which heats the waste gas to a desired temperature, and/or at least one reaction chamber 116 where the waste gas stays and/or is contained, etc., but the example embodiments are not limited thereto. For example, the waste gas reaction unit 110 may include a greater or lesser number of constituent elements, etc.

The waste gas reaction unit 110 may include one or more waste gas inlets 112. In some example embodiments, the waste gas inlet 112 may be disposed on the reaction chamber 116, but is not limited thereto. In other example embodiments, the waste gas inlet 112 may be disposed at a lower and/or side portion of the reaction chamber 116, etc. A waste gas may penetrate into the reaction chamber 116 through the waste gas inlet 112.

The waste gas reaction unit 110 may include one or more heaters 114. To decompose waste gas by using the catalyst processing unit 120, the heater 114 may heat the reaction chamber 116 in order to heat the waste gate flowing into the reaction chamber 116, and may supply heated waste gas to the catalyst processing unit 120, etc. The heater 114 may be a heat source which may heat waste gas, and for example, may correspond to an electric heater, but this is not limited thereto, and various heat sources such as a microwave, plasma, etc. For example, a liquified natural gas (LNG) heater may correspond to the heater 114.

In some example embodiments, the heater 114 may be driven at a desired and/or certain temperature based on at least one chemical material included in the waste gas to decompose the chemical material(s) included in the waste gas. For example, the heater 114 may heat the reaction chamber 116 and waste gas flowing into and/or inside the reaction chamber 116 within a temperature range of approximately 500 degrees C. to approximately 700 degrees C., in order to decompose N₂O included in the waste gas, etc., but the example embodiments are not limited thereto.

The waste gas reaction unit 110 may include the reaction chamber 116. The catalyst processing unit 120 for decomposing a waste gas may be disposed in the reaction chamber 116, but is not limited thereto. In some example embodiments, the reaction chamber 116 may be provided in a cyclone dust collector shape and/or a tapered shape, so as to increase a contact time and a contact area between the catalyst processing unit 120 and the waste gas, but is not limited thereto.

In some example embodiments, an internal space (e.g., interior space, etc.) of the reaction chamber 116 may be divided into, e.g., a first portion P1 where waste gas before being decomposed by the catalyst processing unit 120 stays (e.g., is present, is stored, etc.) and a second portion P2 where waste gas after being decomposed (e.g., decomposed waste gas, etc.) through a chemical reaction with a catalyst material by the catalyst processing unit 120 stays (e.g., is present, is stored, etc.), but the example embodiments are not limited thereto, and for example, the reaction chamber 116 may include a single portion or three or more portions, etc. In some example embodiments, the first portion P1 of the reaction chamber 116 may be apart from the second portion P2 of the reaction chamber 116 with the catalyst processing unit 120 therebetween, but is not limited thereto.

Fine powder may be generated by a physical and/or chemical reaction of waste gas in the reaction chamber 116. For example, the heater 114 may heat waste gas to decompose materials (e.g., materials included in the waste gas, etc.), and thus, fine powder may be generated. For example, fine powder such as a silicone powder having a solid precipitate shape, etc., may be generated from waste gas including silicone. As another example, fine powder including SiO₂ may be generated from waste gas including tetraethyl orthosilicate (TEOS) and/or SiH₄. As described above, a chemical formula where SiH₄ is heated to form SiO₂ may be as follows.

SiH(gas)+2O₂-->SiO₂(fine powder)+2H₂O

In at least one example embodiment, at least one pressure sensor (not shown) may be included in the reaction chamber 116 (for example, in each of the first portion P1 and the second portion P2 of the reaction chamber 116), and a fine powder separation unit 130 described below may supply compressed air as an air pulse when fine powders are accumulated on surfaces of a plurality of catalyst internal cells 124 to have a desired and/or certain thickness or more, but the example embodiments are not limited thereto.

In some example embodiments, the heater 114 may be disposed to surround a sidewall of the reaction chamber 116, with respect to the reaction chamber 116, but is not limited thereto, and the heater 114 may have alternate arrangements, such as being disposed below the reaction chamber 116, inside the reaction chamber 116, etc. In a case where the heater 114 is disposed to surround the sidewall of the reaction chamber 116, the waste gas inlet 112 may be disposed on and/or under the reaction chamber 116. However, the waste gas inlet 112 may be disposed on the reaction chamber 116 based on a flow of a waste gas from the waste gas inlet 112 and a flow of fine powders described below. However, the positions of the waste gas inlet 112, the heater 114, and/or the reaction chamber 116 are not limited to the illustration, and relative positions of the waste gas inlet 112, the heater 114, and/or the reaction chamber 116 may be variously configured.

In some example embodiments, the heater 114 may be efficiently operated and/or controlled to use a decreased and/or minimum power through different temperature settings for each region. For example, the heater 114 may individually heat the first portion P1 of the reaction chamber 116, the second portion P2 of the reaction chamber 116, and/or the catalyst processing unit 120 (e.g., catalyst processor, etc.) to have different temperatures.

The catalyst processing unit 120 (e.g., catalyst processor, etc.) may decompose waste gas heated by the waste gas reaction unit 110. The catalyst processing unit 120 may include at least one catalyst support 122, a plurality of catalyst inner cells 124 passing through the catalyst support 122 in at least one direction (for example, a vertical direction Z), and/or a mount unit 126 which fixes the catalyst support 122 to an inner wall of the reaction chamber 116, but is not limited thereto. In some example embodiments, the catalyst processing unit 120 may be installed in a tray shape and/or a cartridge shape so as to be more easily replaced and/or to improve the case of maintenance of the waste gas scrubber 10, but is not limited thereto.

The catalyst support 122 may be provided in a shape having a desired and/or certain length in the vertical direction (e.g., the Z direction) and may include a first surface 122a which exposes one end (e.g., a first end) of each of the plurality of catalyst inner cells 124 passing through the catalyst support 122 and a second surface 122b which exposes the other end (e.g., a second end) of each of the plurality of catalyst inner cells 124. The first surface 122a of the catalyst support 122 may be connected to the first portion P1 of the reaction chamber 116, and the second surface 122b of the catalyst support 122 may be connected to the second portion P2 of the reaction chamber 116. In some example embodiments, the catalyst support 122 may be provided in a cylindrical shape, a rectangular shape, and/or a hexagonal shape, etc.

In some example embodiments, the one end of each of the plurality of catalyst inner cells 124 may be arranged apart from the first surface 122a of the catalyst support 122 in a first horizontal direction (e.g., an X direction) and/or a second horizontal direction (e.g., a Y direction). The other end of each of the plurality of catalyst inner cells 124 may be arranged apart from the second surface 122b of the catalyst support 122 in the first horizontal direction (e.g., the X direction) and/or the second horizontal direction (e.g., the Y direction). In at least one example embodiment, the one end of each of the plurality of catalyst inner cells 124 may be configured in a grid shape at the first surface 122a of the catalyst support 122, and the other end of each of the plurality of catalyst inner cells 124 may be configured in a grid shape at the second surface 122b of the catalyst support 122, but the example embodiments are not limited thereto.

The plurality of catalyst inner cells 124 may be supported by (e.g., held by, etc.) the catalyst support 122 and may pass through the catalyst support 122 in the vertical direction (e.g., the Z direction), and the one end (e.g., first end) and the other end (e.g., second end) of each of the plurality of catalyst inner cells 124 may be respectively connected to the first portion P1 of the reaction chamber 116 and the second portion P2 of the reaction chamber 116. In other words, the first portion P1 of the reaction chamber 116 and the second portion P2 of the reaction chamber 116 may be connected to each other by the plurality of catalyst inner cells 124, and a fluid of the first portion P1 (e.g., a fluid stored in the first portion P1) of the reaction chamber 116 may flow to the second portion P2 of the reaction chamber 116 through the plurality of catalyst inner cells 124.

In some example embodiments, the plurality of catalyst inner cells 124 may be arranged apart from one another in the first horizontal direction (e.g., the X direction) and/or the second horizontal direction (e.g., the Y direction). For example, one catalyst inner cell 124 selected from among the plurality of catalyst inner cells 124 may be apart from an adjacent catalyst inner cell 124 with a portion of the catalyst support 122 therebetween, but the example embodiments are not limited thereto. In some example embodiments, the plurality of catalyst inner cells 124 may be provided in a cylindrical shape, a tetragonal pillar shape, and/or a hexagonal pillar shape, etc., but is not limited thereto.

The catalyst support 122 and the plurality of catalyst inner cells 124 of the catalyst processing unit 120 may configure a monolith catalyst (e.g., a honeycomb catalyst) which is a type of catalyst, but the example embodiments are not limited thereto. Herein, the monolith catalyst may include the catalyst support 122 and the plurality of catalyst inner cells 124 passing through the catalyst support 122 and may denote a structure where at least one catalyst material is coated on at least one exposed surface of the catalyst support 122 and/or at least one exposed surface of the plurality of catalyst inner cells 124. For example, the catalyst material may be bonded to the surface of the catalyst support 122 and the exterior surfaces the plurality of catalyst inner cells 124 of the catalyst processing unit 120, but is not limited thereto.

For example, the monolith catalyst may include at least one catalyst which is manufactured to be supported by performing oxidation and/or reduction processing on the catalyst support 122 including the plurality of catalyst inner cells 124, etc. The monolith catalyst may have a high specific surface area so that a catalyst is improved and/or optimized as the catalyst material is densely dispersed and/or supported for enlarging a surface area of the catalyst, thereby facilitating contact between the catalyst material and a reactant gas (e.g., the waste gas, etc.).

In some example embodiments, the number of catalyst inner cells 124 may be appropriately set per unit area (e.g., 1 square inch) of the catalyst support 122, but the example embodiments are not limited thereto, and for example, a different unit area may be used. For example, the number of catalyst inner cells 124 per unit area (e.g., 1 square inch) of the catalyst support 122 may be selected based on internal pressure and/or a gas hourly space velocity (GHSV) of a desired waste gas. Here, the GHSV may represent a flow volume of a reactant material per reaction apparatus unit volume.

In some example embodiments, the number of catalyst inner cells 124 per unit area of the catalyst support 122 may be set to approximately 20 to approximately 400, etc., but is not limited thereto. In other words, the number of catalyst inner cells per unit area (e.g., 1 square inch) of the monolith catalyst may be set to approximately 20 CPSI (cell per square inch) to approximately 400 CPSI, but is not limited thereto.

The catalyst processing unit 120 may include at least one catalyst material bonded to the exposed surface of the catalyst support 122 and/or exposed surfaces of the plurality of catalyst inner cells 124. The catalyst material may be material for decomposing a waste gas and may be variously selected based on material included in the waste gas and/or the composition of the waste gas, etc. For example, platinum (Pt), palladium (Pd), and/or rhodium (Rh) may be selected as the catalyst material, but the example embodiments of the inventive concepts are not limited thereto. According to some example embodiments, a plurality of catalyst material may be bonded to one or more of the catalyst support 122 and/or one or more of the plurality of catalyst inner cells 124. For example, a first catalyst material may be bonded to a first catalyst inner cell, a second catalyst material may be bonded to a second catalyst inner cell, etc.

The material(s) of the catalyst support 122 may be variously selected as the material(s) for supporting the catalyst process. However, the inside (e.g., interior) of the reaction chamber 116 may be heated by the heater 114 and may be maintained at a high temperature (e.g., a desired temperature, etc.), but in a case where the fine powder separation unit 130 injects (and/or expels, emits, etc.) compressed air into the reaction chamber 116, because the temperature of the compressed air is relatively lower than an internal temperature of the reaction chamber 116, a rapid temperature change may occur in the reaction chamber 116. A material which is high in thermal stability may be selected as the material of the catalyst support 122 to endure a rapid temperature change caused by the injection of compressed air by the fine powder separation unit 130. For example, alumina and/or cerium oxide/zirconia complex oxide, etc., may be selected as the material of the catalyst support 122, but the example embodiments are not limited thereto.

In some example embodiments, the catalyst processing unit 120 may include at least one binder for bonding the catalyst support 122 to the catalyst material. The binder may include at least one material which is relatively high in bonding force for bonding the catalyst support 122 to the catalyst material so as to endure the injection of compressed air by the fine powder separation unit 130, etc. For example, the catalyst support 122 may include material such as aluminum oxide (Al₂O₃) and/or silicone, etc., but is not limited thereto.

In some example embodiments, the catalyst processing unit 120 may be configured in a multi-layer structure, but is not limited thereto. For example, the catalyst processing unit 120 may include a plurality of catalyst supports 122 which are apart from one another in the vertical direction Z and the plurality of catalyst inner cells 124 which respectively pass through the plurality of catalyst supports 122, etc.

In some example embodiments, waste gas flowing in through the waste gas inlet 112 may stay at the first portion P1 of the reaction chamber 116 and may be heated by the heater 114, and may then move to the plurality of catalyst inner cells 124. A waste gas moving to the plurality of catalyst inner cells 124 may contact catalyst material supported on the surfaces of the catalyst support 122 and/or the surfaces of each of the plurality of catalyst inner cells 124, and may result in a chemical reaction (for example, an oxidation reaction, etc.). Waste gas decomposed through chemical reaction with the catalyst material in the plurality of catalyst inner cells 124 may be collected in the second portion P2 of the reaction chamber 116.

In some example embodiments, some fine powders generated from the chemical reaction of the waste gas contacting the catalyst material may fall with gravity to pass through the plurality of catalyst inner cells 124, and then, may pass through the second portion P2 of the reaction chamber 116 and a first pipe 142 connected to the second portion P2 of the reaction chamber 116, and may be collected in a wet tank 152. Fine powders obtained through primary wet-processing by the wet tank 152 may be precipitated and may be discharged to the outside through a drain port 154, but is not limited thereto. Additionally, and/or alternatively, the fine powders may pass through a second pipe 162 connected to the wet tank 152 and may be collected in a wet tower 172. Fine powders obtained through secondary wet-processing by the wet tower 172 may be precipitated, collected in the wet tank 152 through gravity, and discharged to the outside (e.g., an external destination) through the drain port 154. Detailed elements of the wet tank 152 and the wet tower 172 will be described below.

Also, some of the fine powders may accumulate on the surfaces of the catalyst support 122. Herein, the surfaces of the catalyst support 122 may be defined as including the exposed surfaces of the catalyst 122 and exposed surfaces of the plurality of catalyst inner cells 124 also.

The fine powder separation unit 130 (e.g., fine powder separator, fine powder separation device, etc.) may inject (e.g., expel, emit, etc.) compressed air as an air pulse toward the catalyst support 122 to physically separate the fine powders accumulated on the surface of the catalyst support 122 from the surfaces of the catalyst support 122, etc. Herein, compressed air (e.g., air) used in the air pulse may be understood as including an arbitrary inert gas and/or gas material, which may include air but is not limited thereto.

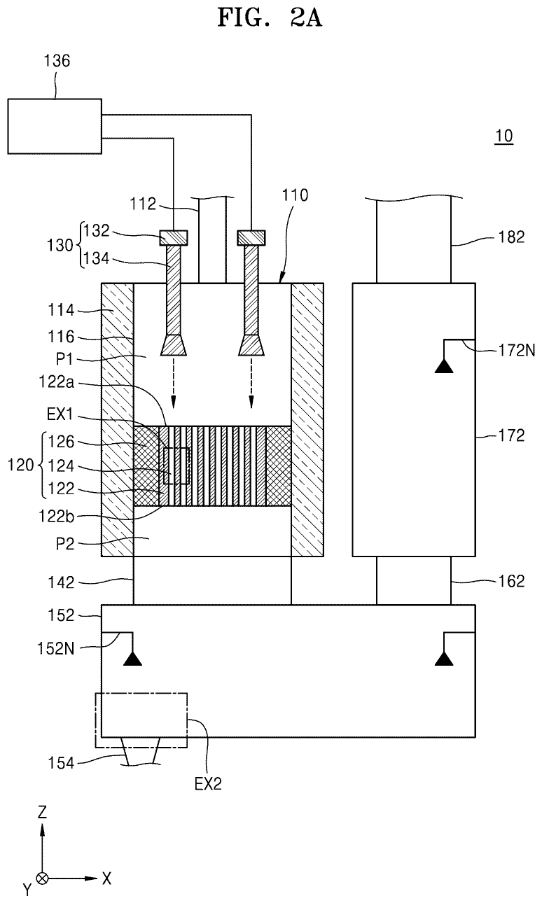

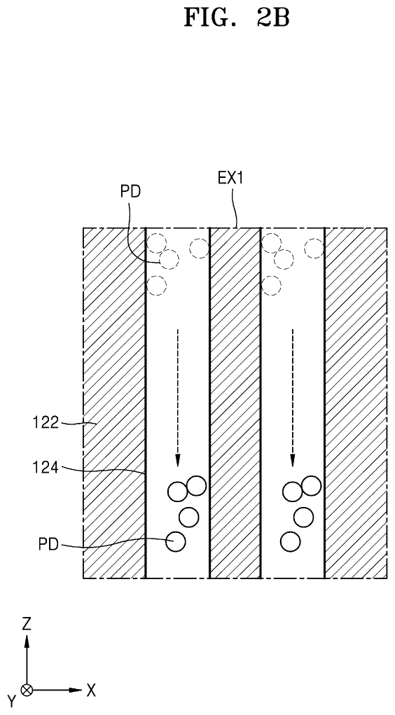

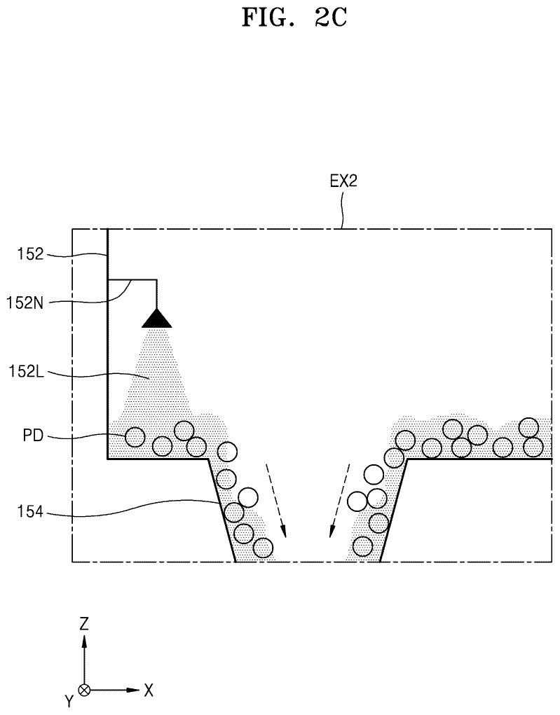

The reason that the fine powder separation unit 130 uses a method of injecting compressed air for a desired pulse of time may be for instantaneously supplying compressed air to apply an impact to the fine powders accumulated on the surface of the catalyst support 122 to more efficiently separate the fine powders from the surface of the catalyst support 122, but is not limited thereto. A method of separating fine powder using the fine powder separation unit 130 will be described in greater detail with reference to FIGS. 2A to 2C.

In some example embodiments, the fine powder separation unit 130 may include an air pulse control valve 132 and/or an air pulse nozzle 134, etc., which are provided as a pulse valve, but is not limited thereto. Herein, the pulse valve may be a valve which is used for controlling a flow of fluid and may denote a valve which performs an operation of blocking and/or opening a flow of fluid so as to generate a pulse a plurality of times. In some example embodiments, the air pulse nozzle 134 may be provided as a diffuser nozzle, but is not limited thereto. For example, the air pulse nozzle 134 may be provided as an air-knife nozzle, a circular nozzle, etc.

In some example embodiments, the number of air pulse control valves 132 and/or air pulse nozzles 134 is not limited thereto, and each of the air pulse control valve 132 and the air pulse nozzle 134 may be provided as one or more, based on a size of the monolith catalyst configured with the catalyst support 122 and the plurality of catalyst inner cells 124 and/or the number of catalyst inner cells 124 per unit area (e.g., 1 square inch) of the monolith catalyst, etc. For example, the number of air pulse control valves 132 and/or air pulse nozzles 134 may be set to one to six, but is not limited thereto.

In some example embodiments, the fine powder separation unit 130 may be connected to the first portion P1 of the reaction chamber 116 and may be apart from the second portion P2 of the reaction chamber 116 with the monolith catalyst therebetween, but is not limited thereto. In some example embodiments, the fine powder separation unit 130 may be disposed on the catalyst processing unit 120. However, the example embodiments are not limited thereto, and the fine powder separation unit 130 is not limited to being disposed on the catalyst processing unit 120 and, for example, may be disposed at a lower power or a side portion of the catalyst processing unit 120, etc.

In some example embodiments, in order to secure appropriate pressure which enables the air pulse control valve 132 and/or the air pulse nozzle 134 to inject fluid (e.g., compressed air, etc.) for a short time to separate a fine powder from the surface of the catalyst support 122, a diameter of an internal cross-sectional area of each of the air pulse control valve 132 and/or the air pulse nozzle 134 may be set to, e.g., approximately 0.5 inches to approximately 10 inches, but are not limited thereto.

In some example embodiments, a pressure of compressed air injected by the fine powder separation unit 130 may be set to, e.g., approximately 2 barG to approximately 8 barG. However, the example embodiments are not limited thereto, and a pressure of an appropriate range may be selected for decreasing and/or preventing the damage of the monolith catalyst while removing the fine powder. For example, when a pressure of compressed air injected by the fine powder separation unit 130 is relatively low, the separation of fine powders may not be performed well, and when the pressure of the compressed air injected by the fine powder separation unit 130 is relatively high, a catalyst material bonded to the exposed surfaces of the catalyst support 122 and/or the exposed surfaces of the plurality of catalyst inner cells 124 may separate from the catalyst support 122, etc.

In some example embodiments, the air pulse control valve 132 may be disposed outside the reaction chamber 116 so as to avoid a degradation caused by the heater 114, and the air pulse nozzle 134 may extend from the air pulse control valve 132 to an inner portion of the reaction chamber 116 (for example, the first portion P1 of the reaction chamber 116). The air pulse control valve 132 may be connected to an air tank storing air, and by opening or closing the air pulse control valve 132, the air pulse nozzle 134 may inject compressed air or may not inject the compressed air into the reaction chamber 116 from the air tank disposed outside the reaction chamber 116, whereby the compressed air may be relatively lower in temperature than the inside of the reaction chamber 116.

In some example embodiments, the waste gas inlet 112 and/or the air pulse nozzle 134 may be disposed to face one end of each of the plurality of catalyst inner cells 124, namely, to face the first surface 122a of the catalyst support 122, but are not limited thereto. In at least one example embodiment, the waste gas inlet 112 and the air pulse nozzle 134 may face the first surface 122a of the catalyst support 122 and may be connected to the first portion P1 of the reaction chamber 116.

In some example embodiments, the air pulse nozzle 134 may inject compressed air in the same direction as an extension direction of the plurality of catalyst inner cells 124, so as to efficiently separate fine powders accumulated in the plurality of catalyst inner cells 124. For example, in a case where the plurality of catalyst inner cells 124 extends in the vertical direction (e.g., the Z direction) in the catalyst support 122 and the air pulse nozzle 134 faces the first surface 122a of the catalyst support 122, the air pulse nozzle 134 may inject compressed air in the vertical direction (e.g., the Z direction) toward the first surface 122a of the catalyst support 122.

In some example embodiments, the air pulse nozzle 134 may inject compressed air in the same direction as a flow direction of waste gas flowing through the waste gas inlet 112, so as to efficiently separate fine powders accumulated in the plurality of catalyst inner cells 124. For example, in a case where the waste gas inlet 112 and the air pulse nozzle 134 face the first surface 122a of the catalyst support 122, the air pulse nozzle 134 may inject compressed air toward the first surface 122a of the catalyst support 122, etc.

For example, when a pressure difference between the first portion P1 of the reaction chamber 116 on the monolith catalyst and the second portion P2 of the reaction chamber 116 under the monolith catalyst corresponds to a range of approximately 5 mmH₂O to approximately 140 mmH₂O, the fine powder separation unit 130 may inject compressed air as an air pulse into the first portion P1 of the reaction chamber 116, but the example embodiments are not limited thereto.

In some example embodiments, the air pulse control valve 132 may be connected to an air pulse controller 136 (e.g., processing circuitry, etc.), so as to control the injection of compressed air by the air pulse nozzle 134. The air pulse controller 136 may control opening and/or closing of the air pulse control valve 132 based on a desired time for supplying compressed air, a timing for supplying the compressed air, the number of supply of the compressed air (e.g., the number of air pulses), a portion-based pressure of the reaction chamber 116, or any combinations thereof. According to some example embodiments, the air pulse controller 136 may be implemented as processing circuitry. Processing circuitry may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

In at least one example embodiment, a supply period of compressed air may be set by the air pulse controller 136. In detail, in addition to continuously supplying compressed air, the compressed air may also be intermittently supplied for desired time periods as air pulses.

For example, when a waste gas including a large amount of silicone flows in, a large amount of fine powders may be generated after the waste gas contacts the catalyst, and thus, it may be appropriate that the fine powder separation unit 130 continuously supply the air pulse into the reaction chamber 116. Also, when a waste gas including a small amount of silicone flows in, a small amount of fine powders may be generated, and thus, it may be appropriate that the fine powder separation unit 130 intermittently supplies the compressed air as a plurality of air pulses into the reaction chamber 116 for only a desired and/or certain time.

For example, the air pulse controller 136 may perform control so that the air pulse valve 132 is opened and then closed for one hour, and the air pulse nozzle 134 may inject the compressed air as the air pulse through an opening/closing operation of the air pulse control valve 132 for one hour for which the air pulse control valve 132 is opened and then closed. Then, the air pulse controller 13 may perform control such that the air pulse control valve 132 is closed and the compressed air is not injected for two hours, etc., but the example embodiments are not limited thereto.

In at least one example embodiment, the air pulse controller 136 may set a desired time schedule at which an air pulse is supplied, e.g., to 9 a.m. daily, and at 9 a.m. daily, the air pulse controller 136 may open the air pulse control valve 132 to allow the air pulse nozzle 134 to inject compressed air as the air pulse, etc., but the example embodiments are not limited thereto.

In at least one example embodiment, the number of air pulses and/or a desired frequency of air pulses may be set by the air pulse controller 136. For example, the air pulse controller 136 may perform control so that the air pulse control valve 132 is opened and then closed once, and the air pulse nozzle 134 may inject compressed air once. In at least one example embodiment, the number of pulses for a desired time period (e.g., the number of pulses per hour, the frequency of air pulses, etc.) may be set by the air pulse controller 136. For example, the air pulse controller 136 may perform control so that the air pulse control valve 132 is opened and then closed once per 30 minutes, and the air pulse nozzle 134 may inject compressed air once per 30 minute, etc.

In at least one example embodiment, when there is a pressure difference between the first portion P1 and the second portion P2 of the reaction chamber 116 (for example, a pressure of the first portion P1 of the reaction chamber 116 is greater than that of the second portion P2 of the reaction chamber 116, etc.), or when there is a difference within a desired certain pressure range, the air pulse controller 136 may perform control so that the air pulse control valve 132 is opened.

For example, when the pressure difference between the first portion P1 and the second portion P2 of the reaction chamber 116 is within a pressure range of approximately 5 mmH₂O to approximately 140 mmH₂O, the air pulse controller 136 may open the air pulse control valve 132 to allow the air pulse nozzle 134 to inject compressed air.

In some example embodiments, in a case where the air pulse control valve 132 is provided in plurality, the air pulse controller 136 may control each of the plurality of air pulse control valves 132 individually or together.

Although not shown, a preprocessing device for removing fine powders and/or removing an acid material may be additionally installed in the first portion P1 of the reaction chamber 116, in addition to the fine powder separation unit 130. However, when the waste gas scrubber 10 according to at least one example embodiment is used as a POU scrubber installed at a rear end of semiconductor manufacturing equipment, the particle size of waste gas may be relatively small, and thus, an operation of installing at least one filter for filtering a waste gas in the reaction chamber 116 may be difficult due to the clogging and/or plugging of the filter.

In some example embodiments, the waste gas scrubber 10 may include the wet tank 152 and/or a combination of the wet tank 152 and the wet tower 172. In some example embodiments, each of the wet tank 152 and the wet tower 172 may include one or more liquid injection nozzles 152N and 172N for wet-processing decomposed waste gas. In other example embodiments, each of the wet tank 152 and the wet tower 172 may be replaced with another device, such as a vacuum suction device, etc., for processing of waste gas and/or fine powders, etc.

The wet tank 152 may be connected to the reaction chamber 116 through the first pipe 142, but is not limited thereto. The wet tank 152 may receive waste gas and/or fine powders, decomposed by at least one catalyst, from the reaction chamber 116, and may primarily wet-process the decomposed waste gas and/or fine powders, etc. In detail, some materials of the decomposed waste gas and/or fine powders may be dissolved in a cleaning solution after the cleaning solution is injected (e.g., sprayed, emitted, expelled, etc.) from the liquid injection nozzle 152N of the wet tank 152. For example, ammonia (NH₃), hydrochloric acid (HCl), and/or chlorine (Cl₂), etc., may be dissolved and/or included in the cleaning solution, and/or some materials may be hydrolyzed, etc. The wet tank 152 may provide a storage space of the cleaning solution 152L.

In some example embodiments, the wet tank 152 may include one or more drain ports 154 which pass through a bottom of the wet tank 152, but is not limited thereto. The drain port 154 may discharge byproducts, which are obtained through wet-processing and are collected and precipitated from the wet tank 152, to the outside (e.g., an external destination) of the wet tank 152, but is not limited thereto.

The wet tower 172 may be connected to the wet tank 152 through the second pipe 162. The wet tank 172 may receive decomposed waste gas from the wet tank 152 and may secondarily wet-process the decomposed waste gas and/or fine powders, etc. In detail, similar to the wet tank 152, some materials of the decomposed waste gas and/or fine powders may be dissolved in a cleaning solution by the cleaning solution injected from the liquid injection nozzle 172N of the wet tower 172.

The decomposed waste gas passing through the wet tower 172 may be discharged through at least one waste gas discharge port 182, etc. A gas discharged through the waste gas discharge port 182 may be a finally purified gas and may not include a fine powder. Byproducts, which are obtained through wet-processing and are collected and precipitated from the wet tower 172, may move to the wet tank 152 by gravity and may then be discharged to the outside (e.g., external destination) by the drain port 154. The byproducts discharged by the drain port 154 may include fine powder which has not decomposed through wet-processing by the wet tank 152 and/or the wet tower 172 and remains, etc.

In some example embodiments, the drain port 154 may have a vertical level which is the lowest in the waste gas scrubber 10, and a bottom of the wet tower 172 may have a vertical level which is relatively higher than the bottom of the wet tank 152, but the example embodiments are not limited thereto. For example, according to other example embodiments, the bottom of the wet tower 172 may have a vertical level which is relatively lower than or equal to the bottom of the wet tank 152 and a drain port may be installed at the bottom of the wet tower 172, etc.

FIG. 2A is a schematic diagram for describing the fine powder removal principle of a waste gas scrubber according to some example embodiments.

FIG. 2B is an enlarged view of a region EX1 of FIG. 2A according to at least one example embodiment.

FIG. 2C is an enlarged view of a region EX2 of FIG. 2A according to at least one example embodiment.

Referring to FIGS. 2A to 2C, as described above with reference to FIGS. 1A and 1B, fine powders PD may be formed through and/or by various formation paths from the waste gas. The fine powders PD may be accumulated on the surface of the catalyst support 122. For example, the fine powders PD may be accumulated on an upper surface of the catalyst support 122, etc., but is not limited thereto.

When the fine powders PD are accumulated, the plurality of catalyst inner cells 124 may become clogged and/or the exposed surface of the catalyst support 122 and/or the exposed surfaces of the plurality of catalyst inner cells 124 may be covered by the fine powders PD, and due to this, a contact area between the catalyst and the waste gas may be considerably reduced, causing a reduction in reactivity of the catalyst (e.g., may cause a decrease in the waste gas decomposition efficiency, etc.). Also, as pressure on the first portion P1 of the reaction chamber 116 increases, a pressure difference between the first portion P1 and the second portion P2 of the reaction chamber 116 may increase, and thus, the fine powders PD may be desired and/or need to be removed in order to decrease the pressure difference between the portions of the reaction chamber 116, etc.

As illustrated in FIG. 2B, the fine powder separation unit 130 may inject and/or emit compressed air onto the fine powders PD accumulated on the surfaces of the plurality of catalyst inner cells 124 to separate the fine powders PD from the surface of the catalyst support 122. The fine powders PD separated from the surface of the catalyst support 122 may move to the wet tank 152 through the first pipe 142 along with the waste gas decomposed (e.g., decomposed waste gas) by the catalyst processing unit 120.

In some example embodiments, the fine powder separation unit 130 may inject and/or emit compressed air in a flow direction of the waste gas. Because the fine powder separation unit 130 injects and/or emits the compressed air in the flow direction of the waste gas, the fine powders PD separated from the surfaces of the plurality of catalyst inner cells 124 may move along with the flow of the waste gas, and thus, the fine powders PD may be more efficiently removed from the inside of the plurality of catalyst inner cells 124.

In some example embodiments, waste gas may move from the first portion P1 of the reaction chamber 116 to the second portion P2 of the reaction chamber 116 through the plurality of catalyst inner cells 124. The fine powder separation unit 130 may be disposed apart from the catalyst support 122 and may inject and/or emit compressed air toward the first surface 122a of the catalyst support 122 (e.g., the plurality of catalyst inner cells 124), etc.

As illustrated in FIG. 2C, the fine powders PD may be wet-processed through the one or more liquid injection nozzles 152N included in the wet tank 152, but is not limited thereto. The wet-processed fine powders PD may be collected and precipitated in the cleaner 152L injected and/or emitted through the liquid injection nozzle 152N included in the wet tank 152. The wet-processed fine powders PD may be discharged from the wet tank 152 to the drain port 154.

In some example embodiments, similar to the wet tank 152, the wet tower 172 may wet-process the fine powders PD through the wet tower 172 and/or the one or more liquid injection nozzles 172N included in the wet tower 172, and the wet-processed fine powders PD may be collected and precipitated in a cleaner injected through the liquid injection nozzle 172N of the wet tower 172. The wet-processed fine powders PD may move to the wet tank 152 based on gravity, and then, may be discharged to the drain port 154.

The waste gas scrubber 10 according to one or more example embodiments may separate and/or remove fine powders accumulated in the waste gas scrubber 10 through the fine powder separation unit 130 to improve and/or enhance the reactivity of a catalyst, and may decrease the occurrence of a pressure difference in the reaction chamber 116, thereby providing the waste gas scrubber 10 where waste gas decomposition efficiency is improved and/or enhanced.

In detail, in comparison to a waste gas scrubber of the related art using a pellet-type catalyst, the waste gas scrubber 10 according to one or more example embodiments may use a monolith catalyst, thereby providing a waste gas scrubber where fine powder removal efficiency is improved and/or enhanced, etc.

Furthermore, the fine powder separation unit 130 may be driven so that the direction of compressed air injection of the air pulse nozzle 134 matches a flow direction of a waste gas, thereby providing a waste gas scrubber 10 where fine powder removal efficiency is improved and/or enhanced.

In the related art, separate process management may be needed for removing fine powders. On the other hand, the waste gas scrubber 10 according to one or more example embodiments may remove fine powders simultaneously with waste gas decomposition by a catalyst, and may thus decrease a loss time consumed by facilities stop caused by process management, thereby largely improving and/or enhancing productivity, etc.

Hereinabove, various example embodiments have been described in the drawings and the specification. The example embodiments have been described by using the terms described herein, but these terms have been merely used for describing the inventive concepts and have not been used for limiting a meaning or limiting the scope of the inventive concepts as defined in the following claims. Therefore, it may be understood by those of ordinary skill in the art that various modifications and other equivalent example embodiments may be implemented from the inventive concepts. Accordingly, the spirit and scope of the example embodiments of the inventive concepts may be defined based on the spirit and scope of the following claims.

While various example embodiments of the inventive concepts have been particularly shown and described, it will be understood that various changes in form and details may be made therein without departing from the spirit and scope of the following claims.

What is claimed is:

1. A waste gas scrubber comprising:
a waste gas inlet;
a reaction chamber configured to decompose waste gas flowing in through the waste gas inlet;
at least one heater configured to heat the waste gas flowing into the reaction chamber;
a fine powder separation device configured to emit compressed air; and
a monolith catalyst including a catalyst support, a plurality of catalyst inner cells, and at least one catalyst material, the catalyst support in the reaction chamber and configured to support the plurality of catalyst inner cells, and the at least one catalyst material configured to cause a chemical reaction with the heated waste gas,
the catalyst support including,
a first surface at which a first end of each of the plurality of catalyst inner cells is exposed, and
a second surface at which a second end of each of the plurality of catalyst inner cells is exposed, and
the waste gas inlet and the fine powder separation device face the first surface of the catalyst support.

2. The waste gas scrubber of claim 1, wherein the fine powder separation device is further configured to:
emit the compressed air toward the first surface of the catalyst support.

3. The waste gas scrubber of claim 1, wherein the waste gas inlet and the fine powder separation device are arranged on the first surface of the catalyst support.

4. The waste gas scrubber of claim 1, wherein the fine powder separation device comprises:
at least one air pulse control valve; and
at least one air pulse nozzle connected to the air pulse control valve, the at least one air pulse nozzle configured to emit the compressed air based on whether the air pulse control valve is open or closed.

5. The waste gas scrubber of claim 4, wherein the air pulse nozzle comprises:
a diffuser nozzle, an air-knife nozzle, or a circular nozzle.

6. The waste gas scrubber of claim 1, further comprising:
a wet tank and a wet tower each including at least one liquid injection nozzle;
the wet tank connected to the reaction chamber and the wet tower; and
the wet tank and the wet tower are configured to wet-process the waste gas flowing into the wet tank and the wet tower from the reaction chamber.

7. The waste gas scrubber of claim 1, further comprising:
an air pulse controller configured to control the fine powder separation device by controlling an opening or closing of an air pulse control valve based on a desired time period for emitting the compressed air, a desired time schedule for emitting the compressed air, a desired number of times to emit the compressed air, a sensed pressure of the reaction chamber, or any combinations thereof.

8. The waste gas scrubber of claim 1, wherein the plurality of catalyst inner cells extend in a vertical direction.

9. The waste gas scrubber of claim 1, wherein
an internal space of the reaction chamber is divided into a first portion and a second portion spaced apart from the first portion, the monolith catalyst between the first portion and the second portion;
the waste gas moves from the first portion to the second portion via the monolith catalyst; and
the fine powder separation device is further configured to emit the compressed air in response to an internal pressure of the first portion being greater than an internal pressure of the second portion.

10. The waste gas scrubber of claim 9, wherein the fine powder separation device is further configured to:
emit the compressed air in response to a difference between the internal pressure of the first portion and the internal pressure of the second portion being within a desired pressure range.

11. A waste gas scrubber comprising:
a waste gas inlet;
a reaction chamber connected to the waste gas inlet, the reaction chamber including an internal space, the internal space divided into a first portion and a second portion;
at least one heater configured to heat the reaction chamber;
a catalyst support arranged in the reaction chamber, the catalyst support configured to support a plurality of catalyst inner cells, each of the plurality of catalyst inner cells having at least one catalyst bonded to an exposed portion of each of the plurality of catalyst inner cells, the first portion above the catalyst support in a vertical direction and the second portion below the catalyst support in the vertical direction;
an air pulse control valve arranged outside the reaction chamber; and
an air pulse nozzle connected to the air pulse control valve, the air pulse nozzle configured to emit compressed air into the reaction chamber, and
the waste gas inlet and the air pulse nozzle are connected to the first portion of the reaction chamber.

12. The waste gas scrubber of claim 11, wherein the air pulse nozzle is further configured to:
intermittently emit the compressed air into the reaction chamber for a desired amount of time.

13. The waste gas scrubber of claim 11, wherein the air pulse nozzle is further configured to:
emit the compressed air into the reaction chamber based on a desired time schedule.

14. The waste gas scrubber of claim 11, wherein the air pulse nozzle is further configured to:
emit the compressed air into the reaction chamber at a desired frequency.

15. The waste gas scrubber of claim 11, wherein the air pulse nozzle is further configured to:
emit the compressed air into the reaction chamber in response to a pressure difference between the first portion and the second portion of the reaction chamber being between 5 mmH₂O to 140 mmH₂O.

16. The waste gas scrubber of claim 11, further comprising:
a wet tank and a wet tower each including at least one liquid injection nozzle, each of the at least one liquid injection nozzles configured to emit liquid;
the wet tank being connected to the reaction chamber;
the wet tower being connected to the reaction chamber through the wet tank;
the air pulse control valve and the air pulse nozzle are configured to separate fine powder accumulated on at least one surface of the catalyst support from the at least one surface of the catalyst support; and
the wet tank and the wet tower are configured to,
collect the fine powder separated from the at least one surface of the catalyst support in liquid emitted from the at least one liquid injection nozzle, and discharge the collected fine powder from the waste gas scrubber.

17. A waste gas scrubber comprising:
a waste gas inlet;
a reaction chamber configured to receive a waste gas from the waste gas inlet;
at least one heater configured to heat the waste gas in the reaction chamber;
a monolith catalyst including a catalyst support arranged in the reaction chamber, a plurality of catalyst inner cells supported by the catalyst support, and at least one catalyst material configured to cause a chemical reaction with the waste gas heated by the heater;
a fine powder separation device configured to separate fine powder from at least one surface of the catalyst support, the fine powder generated by the chemical reaction between the at least one catalyst material and the waste gas;
a wet tank connected to the reaction chamber, the wet tank configured to perform a primary wet-process on the waste gas;
a wet tower connected to the wet tank, the wet tower configured to perform a secondary wet-process on the waste gas;
a drain port on a bottom surface of the wet tank; and
a waste gas discharge port on an upper portion of the wet tower.

18. The waste gas scrubber of claim 17, wherein the fine powder separation device includes:
an air pulse control valve provided outside the reaction chamber; and
an air pulse nozzle provided in the reaction chamber, the air pulse nozzle configured to emit compressed air based on the air pulse control valve.

19. The waste gas scrubber of claim 17, wherein
the wet tank is installed at a lower portion or a side portion of the reaction chamber;
the at least one heater is configured to heat the waste gas;
the at least one catalyst material causes a chemical reaction with the waste gas;
the wet tank and the wet tower are configured to wet-process the heated waste gas; and
the waste gas discharge port is configured to discharge the wet-processed waste gas.

20. The waste gas scrubber of claim 17, wherein
the wet tank is installed at a lower portion or a side portion of the reaction chamber;
the fine powder separation device is configured to separate the fine powder from at least one surface of the catalyst support;
the wet tank and the wet tower are configured to wet-process the separated fine powder; and
the waste gas discharge port is configured to discharge the wet-processed fine powder.
